(19) United States
(12) Patent Application Publication
(10) Pub. No.: US 2007/0024471 A1
(43) Pub. Date: Feb. 1, 2007

(54) Systems and methods for secure communication over wired transmission channels

(75) Inventor: James Ronald Booth, Nicholasville, KY (US)

Correspondence Address: LEXMARK INTERNATIONAL, INC.;INTELLECTUAL PROPERTY LAW DEPARTMENT, 740 WEST NEW CIRCLE ROAD, BLDG. 082-1, LEXINGTON, KY, 40550-0999, US

(73) Assignee: Lexmark International, Inc.

(21) Appl. No.: 11/194,214

(22) Filed: Aug. 1, 2005

(51) Int. Cl. H03M 7/00

(52) U.S. Cl. 341/50

(57) ABSTRACT

A method of secure communication includes encoding a communication by separating the communication into at least two communication parts, such that each of the at least two communication parts comprises at least a portion of the communication. The communication parts may further be encoded with random or pseudo-random data. The at least two communication parts are transmitted over separate wired communication channels, and subsequently decoded to reconstruct the communication.

### FIELD OF THE INVENTION

The present invention relates generally to secure communications, and more specifically, to systems and methods for securing communications over one or more wired transmission channels.

### BACKGROUND OF THE INVENTION

The secure transmission of messages over a communication channel is a recurring challenge for those attempting to prevent the unauthorized interception of a message. This issue is particularly ubiquitous in the area of wireless communications, as transmissions may be easily intercepted ‘off air’. In the area of wireless communication numerous security and encryption techniques exist that attempt to hide a message, such as code division multiple access and direct sequence code division multiple access. These methods employ the use of multiple frequencies to make it more difficult for an eavesdropper to retrieve and capture a confidential message.

Because security techniques in the wireless domain typically rely on the use of multiple frequency band channels, those methods are inapplicable to wired transmission channels carrying information at a specified frequency. Additionally, techniques for securely transmitting messages over wired communications are often dedicated to physical security, as the physical security of wired communication channels is relatively easy to ensure. Nevertheless, security of wired communications may be desirable to enhance physical security. Therefore, what is needed are systems and methods for secure communication over wired transmission channels that decrease or impede the ability of eavesdropping by an unauthorized party.

### BRIEF SUMMARY OF THE INVENTION

According to an embodiment of the invention, there is disclosed a method of secure communication. The method includes encoding a communication, where encoding the communication includes separating the communication into at least two communication parts, such that each of the at least two communication parts comprises at least a portion of the communication. The method also includes transmitting the at least two communication parts over separate wired communication channels, and receiving the at least two communication parts from the separate wired communication channels, and decoding the at least two communication parts, where decoding includes reconstructing the communication from the at least two communication parts.

According to an aspect of the invention, encoding the communication further includes encoding the communication with randomly generated data such that at least one of the at least two communication parts includes the randomly generated data. According to another aspect of the invention, transmitting the at least two communication parts includes simultaneously transmitting the at least two communication parts. Transmitting the at least two communication parts may also or additionally include transmitting the at least two communication parts serially. According to yet another aspect of the invention, decoding the at least two communication parts includes decoding the at least two communication parts using, at least in part, a decoding key. Furthermore, according to another aspect of the invention, separating the communication into at least two communication parts may include scrambling the communication.

According to another embodiment of the invention, there is disclosed a method of secure communication. The method includes encoding a communication, where encoding the communication includes separating the communication into at least two communication parts, and where the at least two communication parts include a first communication part and a second communication part. The method further includes transmitting the first communication part over a wired communication channel, and transmitting, subsequent to transmitting the first communication part, the second communication part over the wired communication channel. The method also includes receiving the first communication part and the second communication part from the wired communication channel, and decoding the first communication part and the second communication part, where decoding includes reconstructing the communication from the first communication part and the second communication part.

According to an aspect of the invention, encoding the communication may include encoding the communication with randomly generated data, where at least one of the first communication part and the second communication part includes the randomly generated data. According to another aspect of the invention, decoding the first communication part and the second communication part includes decoding the first communication part and the second communication part using, at least in part, a key. According to yet another aspect of the invention, the transmission of the second communication part does not immediately follow the transmission of the first communication part. Furthermore, separating the communication into at least two communication parts may include scrambling the communication.

According to yet another embodiment of the invention, there is disclosed a system for secure communication. The system includes an encoder operable to receive a communication and further operable to encode the communication, a plurality of wired communication channels, where at least two of the plurality of wired communication channels are operable to receive respective parts of the encoded communication and to transmit the respective parts of the encoded communication, and a decoder operable to receive the respective parts of the encoded communication, and to reconstruct the communication from the respective parts.

According to an aspect of the invention, there is disclosed at least one random data generator in communication with the encoder, where the at least one random data generator is operable to transmit random data to the encoder. According to another aspect of the invention, the encoder is operable to encode the communication using, at least in part, the random data. According to yet another aspect of the invention, the wired communication channels are operable to transmit the respective parts of the encoded communication serially, and/or in parallel.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1 is a block diagram illustration of a communication system, according to an illustrative embodiment of the present invention.

FIG. 2 is a block diagram illustration of a communication system, according to another illustrative embodiment of the present invention.

FIG. 3 shows the secure transmission of a communication using a communication system of the present invention, according to an illustrative embodiment of the present invention.

FIG. 4 shows the secure transmission of a communication using a communication system of the present invention, according to another illustrative embodiment of the present invention.

FIG. 5 shows a block diagram flow chart illustrating a process for securely transmitting a communication, according to an illustrative embodiment of the present invention.

FIG. 6 shows a block diagram flow chart illustrating a process for securely transmitting a communication, according to another illustrative embodiment of the present invention.

### DETAILED DESCRIPTION OF THE INVENTION

The present inventions now will be described more fully hereinafter with reference to the accompanying drawings, in which some, but not all embodiments of the inventions are shown. Indeed, these inventions may be embodied in many different forms and should not be construed as limited to the embodiments set forth herein; rather, these embodiments are provided so that this disclosure will satisfy applicable legal requirements. Like numbers refer to like elements throughout.

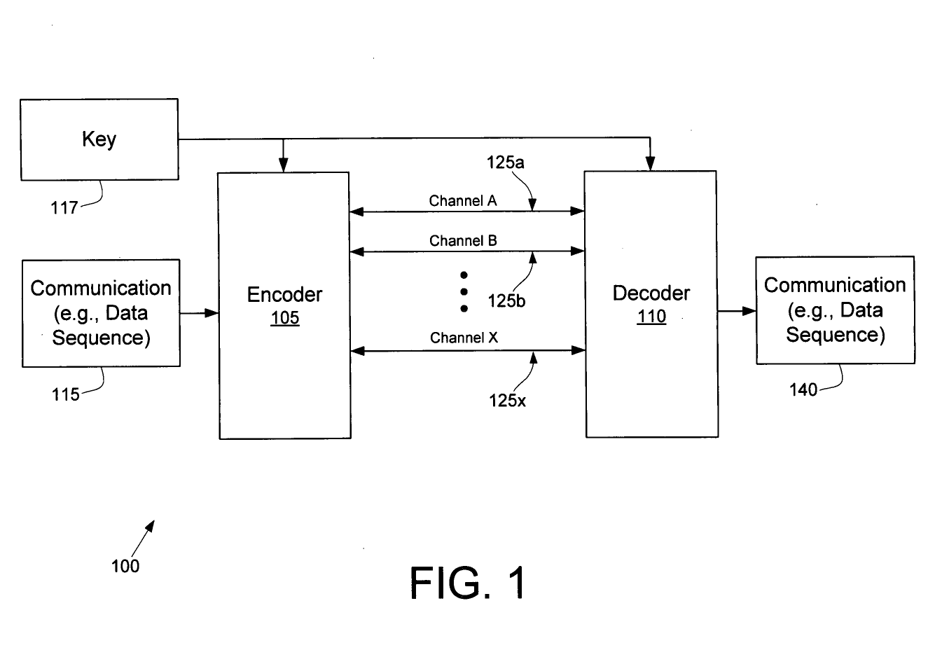

FIG. 1 is a block diagram illustration of a communication system 100, according to an illustrative embodiment of the present invention. The communication system 100 generally includes an encoder 105, a decoder 110, and a plurality of communication channels 125a, 125b, . . . , 125x. The plurality of communication channels 125a, 125b, . . . , 125x are operable to transmit a communication from the encoder 105 to the decoder 110 as described in detail herein. According to one aspect of the invention, the communication channels 125a, 125b, . . . , 125x are wired communication channels. The communication channels 125a, 125b, . . . , 125x may represent conductors operable to transmit data at a consistent frequency.

As illustrated in FIG. 1, the encoder 105 receives, as an input, a communication 115, which according to an aspect of the invention may be a digital communication comprising a data sequence. The encoder 105 is operable to encode the communication 115 so that it may be securely transmitted to the decoder 110 via the communication channels 125a, 125b, . . . , 125x. The secure transmission of the communication 115 protects the communication 115 from being intercepted and reconstructed by an entity other than the decoder 110, which is the intended recipient of the communication 115. More particularly, to effect the secure transmission of the communication the encoder 105 may separate the communication 115 into multiple parts and transmit the parts over the plurality of communication channels 125a, 125b, . . . , 125x.

According to one aspect of the invention, each individual part of the communication 115 may be transmitted over a different channel if enough channels 125a, 125b, . . . , 125x are available. For instance, where four channels are available, the communication 115 may separated into four parts, where each part is transmitted over a different channel. In such an example, the transmission of the multiple communication parts may occur in parallel so that multiple channels are transmitting the communication parts simultaneously. According to another aspect of the invention, one or more of the parts may be carried on the same channel as one or more different parts. For instance, if four channels are available, a communication separated into eight parts may be transmitted to the decoder 110 where each channel carries two parts, transmitted serially by the encoder 105. It will be appreciated by those of ordinary skill in the art that other techniques combining serial and parallel transmission of communication parts may also be achieved using the system 100 shown in FIG. 1. For example, at least a portion of the parts may be transmitted over one or more channels in parallel, while additional parts may be transmitted serially, i.e., on the same channel that transmitted an earlier part.

The encoder 105 carries out the task of encoding the communication by separating it into multiple communication parts. In particular, the encoder 105 may include software and/or hardware for executing an encoding algorithm on a communication 115 to be transmitted. The encoding algorithm can use one or more rules, referred herein as a key 117, to separate the communication into multiple parts. The key 117 dictates how the communication 115 will be broken up by the encoder 105, what channels will be used to transmit communication parts, and how the communication parts will be transmitted over the plurality of channels 125a, 125b, . . . , 125x (e.g., serially, in parallel, or a combination thereof). The key 117 may also be used to scramble the communication 115, and to encrypt one or more communication parts. Although the key 117 is illustrated as supplied to the encoder 105 and decoder 110, the key 117 may alternatively be generated by the encoder 105 and transmitted by the encoder 105 to the decoder 110.

It will further be appreciated that elements of the communication parts, such as digital data or bits, may be scrambled within each communication part. After the encoding of the communication 115 message, including the separation of the communication into two or more communication parts, the communication parts are transmitted over one or more communication channels 125a, 125b, . . . , 125x to the decoder 110. The decoder 110 subsequently receives the communication parts, and using the key 117, or a decoding key corresponding to the key, as is known in the art, the decoder 110 reconstructs the communication 115.

It will be appreciated that the present invention may be implemented using an encoding algorithm that implements well-known encryption techniques. Among other encryption methodologies that may be used with the present invention include Elliptic Curve Cryptography (ECC), Internet security protocols, and the like. To effect such encoding, the encoder 105 and decoder 110 may include additional elements (not illustrated), such as memories to buffer communication parts or data prior to its transmission, processors to execute encoding algorithms, and other elements known to those of ordinary skill in the art. According to one aspect of the invention, the encoding algorithm is executed within the encoder 105. Additionally, encoding techniques that may be employed in the present invention may utilize well known secure methods for exchanging keys to effect encryption, such as the use of public and private keys. As described above, the encoder 105 may transmit the key 117 to the decoder 110 rather than receiving the key like the decoder 110. The key's transmission may also occur, for instance, by an out-of-band communication or by in-band protocols using asymmetric encryption methodologies. Other key exchange methods and techniques for securely providing the decoder with keys or algorithms to reconstruct the encoded communication 115 are known to those of ordinary skill in the art. It will also be appreciated that other hardware and/or software may be included within the system 100 to effect the encoding of the communication and the decoding, or reconstruction, of the communication.

Although the system 100 illustrated in FIG. 1 shows multiple communication channels 125a, 125b, . . . , 125x, it will be appreciated that a communication may be securely transmitted using only a single channel. For instance, the encoder 105 of FIG. 1 may separate the communication 115 into multiple communication parts that are scrambled, and transmitted in serial to the decoder 110. Because such serial communications may occur on a single communication channel, secure transmissions may be sent on a single channel rather than requiring multiple channels.

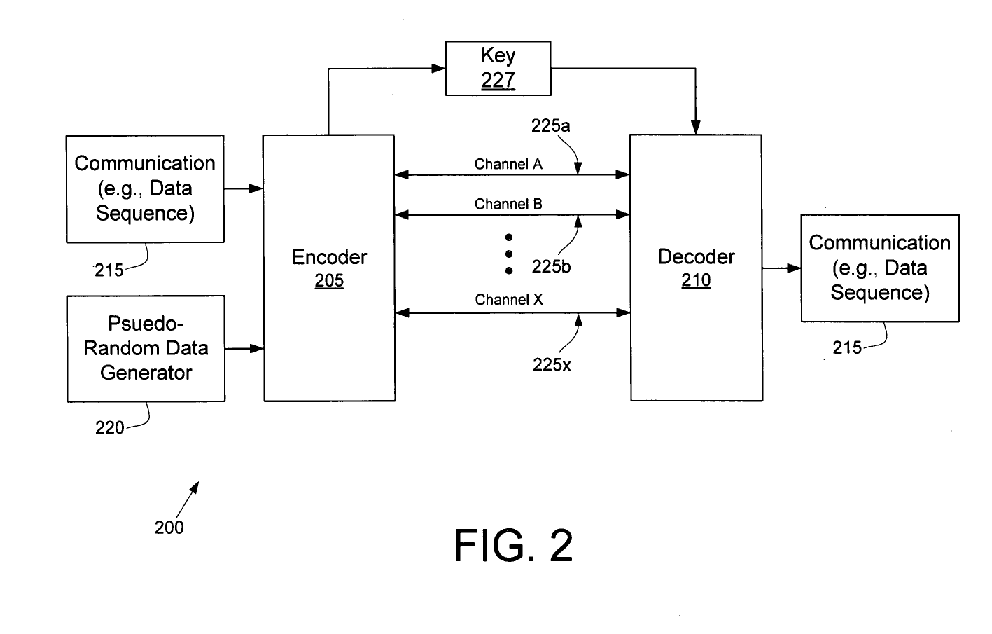

Next, FIG. 2 is a block diagram illustration of a communication system 200, according to another illustrative embodiment of the present invention. Similar to the communication system 100 of FIG. 1, the communication system 200 of FIG. 2 includes an encoder 205 that receives a communication, such as a data sequence 215, and encodes the communication for transmission to a decoder 210 over one or more communications channels 225a, 225b, . . . , 225x. According to one aspect of the invention, the communication channels 225a, 225b, . . . , 225x are wired communication channels and may represent conductors operable to transmit data at a consistent frequency. However, unlike the communication system 100 of FIG. 1, the encoder 205 of the communication system 200 receives pseudo-random data from a pseudo-random data generator 220. The encoder 205 encodes the communication 215 by combining the communication 215 with the pseudo-random data.

More specifically, the encoder 205 is operable to separate the data sequence 215 into multiple communication parts, and combine one or more of the communication parts with the pseudo-random data. Even if one or more of the communications channels 225a, 225b, . . . , 225x are intercepted, for instance by an unauthorized entity, reconstruction of the communication 215 is difficult for the same reasons discussed above with respect to FIG. 1, and because it may be difficult or impossible to determine what portions of each communication part include pseudo-random data, and what portions contain the actual portion of the original communication 215.

It will be appreciated that any amount of pseudo-random data may be combined with the communication 215 to generate encoded communication parts transmitted over the one or more channels 225a, 225b, . . . , 225x. The amount of pseudo-random data added to one or more communication parts adds, however, to the bandwidth required for the transmission of the communication. Therefore, the addition of pseudo-random data may increase security at the expense of additional bandwidth.

Like the illustrative embodiment shown in FIG. 1, after the decoder 210 receives the communication parts from the one or more channels 225a, 225b, . . . , 225x, the decoder 210 will utilize a key 227 to reconstruct the communication 215. The key 227 in the embodiment shown in FIG. 2 is generated by the encoder 205 and transmitted to the decoder 210, although alternatively it may also be supplied to both the encoder 205 and decoder 210 as described above with reference to FIG. 1. Further, though the system 200 illustrated in FIG. 2 shows multiple communication channels 225a, 225b, . . . , 225x, it will be appreciated that a communication may be securely transmitted using only a single channel. It will also be appreciated that the encoder 205 and decoder 210 of FIG. 2 may be similar to those described above with respect to FIG. 1, but for the additional ability to encode the communication using pseudo-random data or random data.

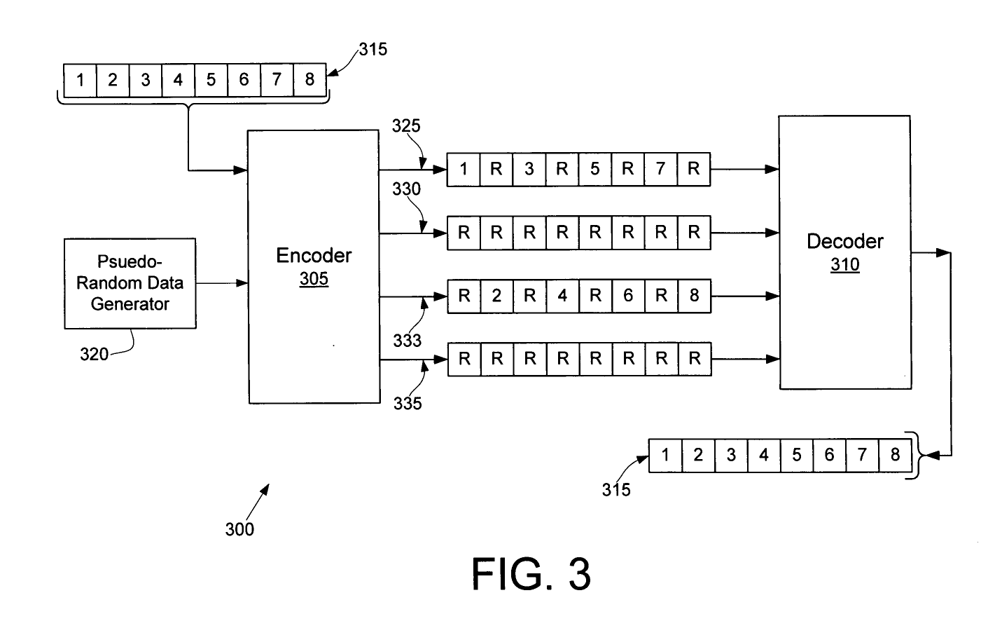

FIG. 3 shows the secure transmission of a communication 315 using a communication system 300 according to an exemplary embodiment of the present invention. In particular, the communication system 300 shown in FIG. 3 is similar to that described above with respect to FIG. 2, in that the system 300 encodes the communication 315 using pseudo-random data provided by a pseudo-random data generator 320. In FIG. 3, the communication 315 includes 8 bits, where each respective bit is represented by a number 1-8 for illustrative purposes. Additionally, the pseudo-random data provided by the pseudo-random data generator 320 is generically referenced in FIG. 3 as including bits designated in the figure by “R”.

The encoder 305 is operable to encode the communication 315 by separating the communication 315 into at least two communication parts each including a portion of the communication 315. The encoder 305 is further operable to encode the communication with the pseudo-random data, as described above with respect to FIG. 2. As shown in the example of FIG. 3, the encoded communication includes at least two communication parts transmitted over the channels 325, 330, 333, 335 generally positioned between the encoder 305 and decoder 310. In particular, the communication 315 is transmitted via two communication parts over two channels 325, 333, where the odd bits (1, 3, 5, 7) of the communication 315 are transmitted over a first channel 325, and the even bits (2, 4, 6, 8) of the communication 315 are transmitted over a second channel 333. As shown in FIG. 3, the even and odd bits of the communication 315 are also encoded with pseudo-random data bits “R” on the first and second channels 325, 333. The pseudo-random data is also transmitted on the third and fourth channels 330, 335, that do not carry any portion of the communication 315.

Upon receipt of the information carried on each of the four channels 325, 330, 333, 335 the decoder 310 reconstructs the communication 315 by extracting the bits corresponding to the communication 315, that is, the odd bits (1, 3, 5, 7) carried on the first channel 325 and the even bits (2, 4, 6, 8) carried on the third channel 333. The decoder 310 uses the key (not illustrated) to extract the communication bits. As described above with reference to FIGS. 1 and 2, the key may be provided to the encoder 305 and decoder 310, or may be provided to the decoder 310 from the encoder 305. The key also informs the decoder to ignore the pseudo-random data transmitted on the second and fourth channels 330, 335, as well as the pseudo-random data transmitted along with the communication bits on the first channel 325 and third channel 333.

It will be appreciated that FIG. 3 represents an illustrative example of the secure transmission of a communication using the present invention. Thus, the scheme by which the communication bits may be split up over one or more channels may vary, depending on the encoding algorithm implemented by the encoder 305. For instance, although the respective even and odd bits of the communication 315 are shown in order and separated, respectively, by pseudo-random bits “R”, the communication bits may be scrambled such that they are not in order within a communication part transmitted over a single channel. Because the order of bit transmission may change, the encoder may buffer the communication 315 and/or the pseudo-random data before encoding and transmitting the communication 315. Furthermore, any order of random bits and communication bits may be transmitted, such that there is no apparent sequence of pseudo-random bits and communication bits in one or more of the channels 325.

It may be advantageous is recurring sequences, such as the alternating communication bits and pseudo-random bits shown in FIG. 3, are not transmitted via the one or more channels to reduce the possibility that an unauthorized party could decode the encoded communication despite not having the key. It will also be appreciated that the pseudo-random bits be similar to that of the communication bits so that the pseudo-random bits are not easily identified. Nevertheless, rather than pseudo-random data, random data provided by a random data generator may also be used to effect the systems and methods of the present invention. Because the communication 315 is split up among the communication channels and combined with pseudo-random data, it will be appreciated that the reconstruction of the communication 315 is difficult or impossible, as reconstruction requires the identification of all of the communication bits and the order of all of the communication bits.

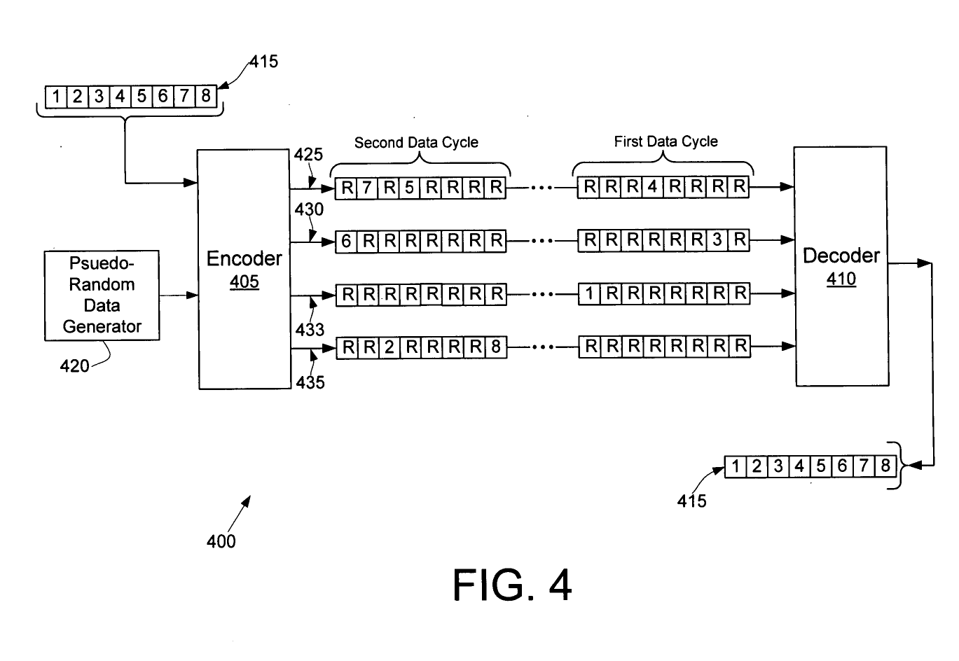

Next, FIG. 4 shows the secure transmission of an illustrative communication using a communication system 400 of the present invention, according to another exemplary embodiment of the present invention. In particular, FIG. 4 illustrates that a communication 415 may be transmitted at different times, i.e., serially, over one or more channels in addition to the transmission of the communication in separate parts with random data via one or more channels, as in the illustrative example of FIG. 3.

The illustrative communication shown in FIG. 4 is identical to the communication 315 described above with respect to FIG. 3. The communication 415 includes 315 includes 8 bits, where each respective bit is represented by a number 1-8 for illustrative purposes. As shown in FIG. 4, an encoder 405 is operable to encode the communication 415 by separating it into multiple communication parts, and by transmitting it along with pseudo-random data, represented by pseudo-random bits “R” and provided by a pseudo-random data generator 420. However, unlike the illustrative example in FIG. 3, at least some of the encoded communication parts are transmitted serially on a single communication channel.

As shown in FIG. 4, the communication parts may be transmitted serially on one or more communication channels 425, 430, 433, 435 in separate data cycles, where a second data cycle is transmitted subsequent to a first data cycle. For instance, in the illustrative example of FIG. 4, the first data cycle includes the transmission of three communication bits (4, 3, 1) on three respective communication channels 425, 430,433. Each of the three respective communication channels 425, 430, 433 also carry pseudo-random bits, while the fourth communication channel 435 carries all pseudo-random bits. After the first data cycle is transmitted, a second data cycle may be transmitted via one or more of the same communication channels 425, 430, 433, 435. In the example of FIG. 4, the second data cycle includes the transmission of the remaining five bits (7, 5, 6, 8, 2) of the communication 415, on three communication channels 425, 430, 435.

It will be appreciated with reference to FIGS. 3 and 4 that a communication may be encoded by separating it for transmission over multiple channels, by encoding it with pseudo-random (or random) data, and by transmitting it serially or in parallel. Additionally, elements of each communication, such as communication bits, may be scrambled within each separately transmitted communication part, and may be combined in any order or sequence with pseudo-random data. For instance, as shown in FIG. 4, a communication bit, such as communication bit 4, may be transmitted before a communication bit 2 that may be occur earlier in the communication. As another example, communication bits on a particular channel and within a single data cycle may also be reversed, as in bits 7 and 5. Therefore, it will be appreciates that an encoding algorithm may utilize any combination of the above-described techniques for encoding a communication.

As with the example shown in FIG. 3, upon receipt of the information carried on each of the four channels 425, 430, 433, 435 the decoder 410 reconstructs the communication 415 by extracting the bits corresponding to the communication 415 by using the key provided by the encoder 405. As described above with reference to FIGS. 1 and 2, the key may be provided to the encoder 405 and decoder 410, or may be provided to the decoder 410 from the encoder 405. The key also informs the decoder to ignore the pseudo-random data transmitted on the channels 425, 430, 433, 435.

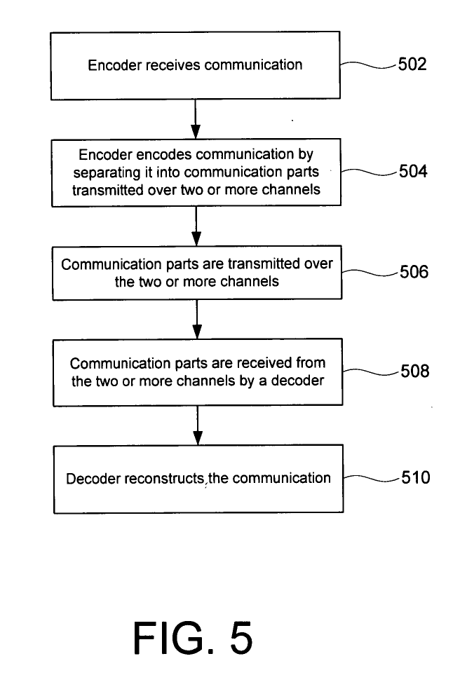

FIG. 5 shows a block diagram flow chart illustrating a process for securely transmitting a communication, according to an illustrative embodiment of the present invention. As illustrated, after an encoder receives a communication (block 502), the encoder encodes the communication (block 504) by separating it into communication parts using an encoding algorithm. The encoder may optionally also encode the communication by combining it, at least in part, with pseudo-random or random data. After encoding the communication, the communication parts are transmitted over two or more channels (block 506) to a decoder, which receives the communication parts (block 508). The decoder then reconstructs the communication (block 510) from the communication parts using at least one key.

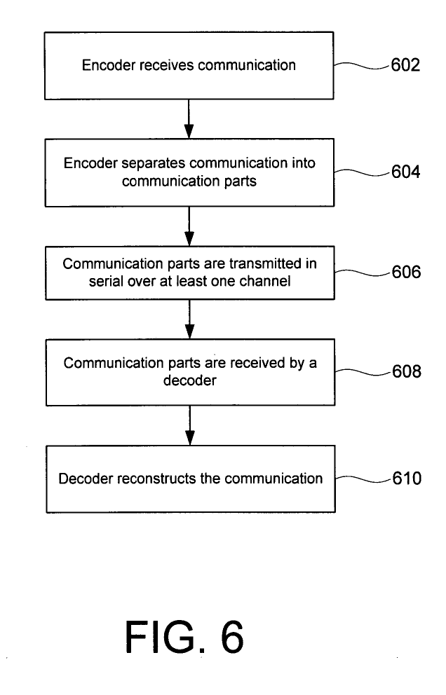

FIG. 6 shows a block diagram flow chart illustrating a process for securely transmitting a communication, according to another illustrative embodiment of the present invention. As shown in FIG. 6, after an encoder receives a communication (block 602), the encoder encodes the communication (block 604) by separating it into communication parts using an encoding algorithm. The encoder may optionally also encode the communication by combining it, at least in part, with pseudo-random or random data. After encoding the communication, the communication parts are transmitted in serial over one or more channels (block 606). Thereafter, a decoder receives the communication parts (block 608) and reconstructs the communication (block 610) from the communication parts using at least one key.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. A method of secure communication, comprising:
encoding a communication, wherein encoding the communication comprises separating the communication into at least two communication parts, such that each of the at least two communication parts comprises at least a portion of the communication;
transmitting the at least two communication parts over separate wired communication channels;
receiving the at least two communication parts from the separate wired communication channels; and
decoding the at least two communication parts, wherein decoding comprises reconstructing the communication from the at least two communication parts.

2. The method of claim 1, wherein encoding the communication further comprises encoding the communication with randomly generated data, and wherein at least one of the at least two communication parts comprises the randomly generated data.

3. The method of claim 1, wherein transmitting the at least two communication parts comprises simultaneously transmitting the at least two communication parts.

4. The method of claim 1, wherein decoding the at least two communication parts comprises decoding the at least two communication parts using, at least in part, a decoding key.

5. The method of claim 1, wherein transmitting the at least two communication parts comprises serially transmitting the at least two communication parts.

6. The method of claim 1, wherein separating the communication into at least two communication parts comprises scrambling the communication.

7. A method of secure communication, comprising:
encoding a communication, wherein encoding the communication comprises separating the communication into at least two communication parts, and wherein the at least two communication parts comprise a first communication part and a second communication part;
transmitting the first communication part over a wired communication channel;
transmitting, subsequent to transmitting the first communication part, the second communication part over the wired communication channel;
receiving the first communication part and the second communication part from the wired communication channel; and
decoding the first communication part and the second communication part, wherein decoding comprises reconstructing the communication from the first communication part and the second communication part.

8. The method of claim 7, wherein encoding the communication further comprises encoding the communication with randomly generated data, and wherein at least one of the first communication part and the second communication part comprises the randomly generated data.

9. The method of claim 7, wherein decoding the first communication part and the second communication part comprises decoding the first communication part and the second communication part using, at least in part, a decoding key.

10. The method of claim 7, wherein the transmission of the second communication part does not immediately follow the transmission of the first communication part.

11. The method of claim 7, wherein separating the communication into at least two communication parts comprises scrambling the communication.

12. A system for secure communication, comprising:
an encoder operable to receive a communication and further operable to encode the communication;
a plurality of wired communication channels, wherein at least two of the plurality of wired communication channels are operable to receive respective parts of the encoded communication, and to transmit the respective parts of the encoded communication; and
a decoder, wherein the decoder is operable to receive the respective parts of the encoded communication, and to reconstruct the communication from the respective parts.

13. The system of claim 12, further comprising at least one random data generator in communication with the encoder, wherein the at least one random data generator is operable to transmit random data to the encoder.

14. The system of claim 13, wherein the encoder is operable to encode the communication using, at least in part, the random data.

15. The system of claim 13, wherein the wired communication channels are operable to transmit the respective parts of the encoded communication serially.

16. The system of claim 13, wherein the wired communication channels are operable to transmit the respective parts of the encoded communication in parallel.
